(19) United States
(12) Patent Application Publication
(10) Pub. No.: US 2005/0265497 A1
(43) Pub. Date: Dec. 1, 2005

(54) Signal processor

(75) Inventors: Yoshiki Matsumoto, Osaka (JP); Ichiro Kawashima, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/082,909

(22) Filed: Mar. 18, 2005

(30) Foreign Application Priority Data
Jun. 1, 2004 (JP) 2004-163415

(51) Int. Cl. H03D 3/18

(52) U.S. Cl. 375/350; 375/328

(57) ABSTRACT

When the filtering is necessary, a filtering operation section performs a filtering operation on received data in response to a control signal output from a filtering on/off control section to generate data to be output. On the other hand, when the filtering is unnecessary, an output selection section extracts specified delay data out of the delay data stored in the delay buffer in response to a control signal output from a filtering on/off control section and outputs the extracted data.

### CROSS-REFERENCE TO RELATED APPLICATION

This non-provisional application claims priority under 35 U.S.C. §119(a) on Patent Application No. 2004-163415 filed in Japan on Jun. 1, 2004, the entire contents of which are hereby incorporated by reference.

### BACKGROUND OF THE INVENTION

(a) Field of the Invention The present invention relates to a signal processor capable of on/off switching of filtering.

(b) Description of Related Art

In acoustic signal reproduction equipment such as DVD players, digital television sets, cellular phones and electronic musical instruments, filtering has conventionally been implemented using a signal processor such as a digital signal processor to give acoustic effects (e.g., chorus and reverb) or extract a signal of a required frequency band.

To perform the filtering with use of the above-described signal processor, for example, the filtering is constantly kept on, or alternatively, the filtering is switched between on and off during reproduction when a suitable filter is automatically selected in response to a characteristic of an input signal or a user turns on or off the acoustic effect of the acoustic signal reproduction equipment.

FIG. 1 is a block diagram illustrating a configuration of a conventional signal processor capable of on/off switching of the filtering. In FIG. 1, reference numeral 101 is a filtering on/off switch for selecting the on or off state of the filtering, 102 is a delay buffer which sequentially delays received data and stores the delay data and 103 is a filtering operation section which performs a filtering operation. The delay buffer 102 is usually constituted of a shift resister or a memory.

When the filtering on/off switch 101 is in the on state, input data is received by the delay buffer 102 and sequentially delayed by the delay buffer 102 to generate delay data. The delay data is stored in the delay buffer 102. Then, the filtering operation section 103 performs a filtering operation using the delay data in the delay buffer 102, i.e., a product-sum operation on the delay data and a filter coefficient, thereby generating data to be output.

When the filtering on/off switch 101 is in the off state, input data is output as it is without being delayed or stored in the delay buffer 102.

However, when the filtering is switched from the off state to the on state in the signal processor of the above-described configuration, the delay data generated and stored in the previous filtering-on state remains in the delay buffer 102. Therefore, discontinuity occurs at the boundary between the remaining data and newly input data. Therefore, when the filtering operation is performed with the delay buffer 102 retaining the delay data generated in the previous filtering-on state, the discontinuity occurs also in the output data, thereby causing noise.

For the above reason, there has been developed a method for preventing the noise by clearing the delay buffer to erase the remaining data or masking the output data (for example, see Japanese Unexamined Patent Publication No. HE15-61493).

According to this method, the influence of the data remaining from the previous filtering-on state can be avoided. However, as shown in FIG. 2, data of 0 or almost 0 is output in a period immediately after the filtering is switched from the off state to the on state until the delay buffer is filled with the newly input data. This presents another problem of the occurrence of audible noise due to the discontinuity of the output data.

To cope with the problem, there has been developed a method for preventing the noise which occurs immediately after the switching of the filtering (for example, see Japanese Unexamined Patent Publication No. HEI10-161657). According to this method, a filter coefficient is gradually changed, or alternatively, two delay buffers including a delay buffer A for storing input data and a delay buffer B for storing filtered data are provided such that, when the filtering state is changed, the data in the delay buffer A is output until the delay buffer B is filled with the data.

### SUMMARY OF THE INVENTION

Although the above-described method allows preventing the noise from occurring, it requires additional means for gradually changing the filter coefficient or the two delay buffers. This complicates the configuration of the processor, thereby entailing higher cost than that of the signal processor as shown in FIG. 1.

Under these circumstances, the present invention has been achieved. In respect of a signal processor capable of on/off switching of the filtering, an object of the present invention is to prevent the noise from occurring during the on/off switching of the filtering with a low-cost configuration at no significant increase in circuit dimension and program size.

More specifically, the present invention provides a signal processor comprising: a delay buffer which delays input data to generate delay data and stores the delay data; a filtering on/off control section which outputs a control signal for turning filtering on or off; an output selection section which extracts and outputs specified delay data from the delay buffer in response to the control signal output from the filtering on/off control section; and a filtering operation section which performs a filtering operation on the delay data stored in the delay buffer in response to the control signal output from the filtering on/off control section and outputs the operation result.

The present invention further provides a signal processor comprising: a delay buffer which delays input data to generate delay data and stores the delay data; a filtering on/off control section which outputs a control signal for turning filtering on or off; a filtering operation section which performs a filtering operation on the delay data stored in the delay buffer and outputs the operation result; and a filter coefficient determination section which changes a filter coefficient of the filtering operation section in response to the control signal output from the filtering on/off control section.

Further, in the present invention, the filter coefficient determination section may be so configured that a filter coefficient required for the filtering operation is determined when a control signal for turning the filtering on is output from the filtering on/off control section, or a filter coefficient for specified delay data is determined as “1” and a filter coefficient for the other delay data is determined as “0” when a control signal for turning the filtering off is output from the filtering on/off control section.

Thus, the present invention allows preventing the noise from occurring during the on/off switching of the filtering. Since the processor configuration is simple, the present invention is easy to realize. Further, the noise prevention is achieved at low costs without any significant increase in circuit dimension and program size.

### BRIEF DESCRIPTION OF THE DRAWINGS

FIG. 1 is a block diagram illustrating a configuration of a conventional signal processor.

FIG. 2 is a graph of output data when the filtering is switched from the off state to the on state in the conventional signal processor.

FIG. 3 is a block diagram illustrating a configuration of a signal processor according to Embodiment 1 of the present invention.

FIG. 4 is a block diagram illustrating a detailed configuration of the signal processor according to Embodiment 1 of the present invention.

FIG. 5 is a block diagram illustrating a configuration of a signal processor according to Embodiment 2 of the present invention.

FIG. 6 is a block diagram illustrating a detailed configuration of the signal processor according to Embodiment 2 of the present invention.

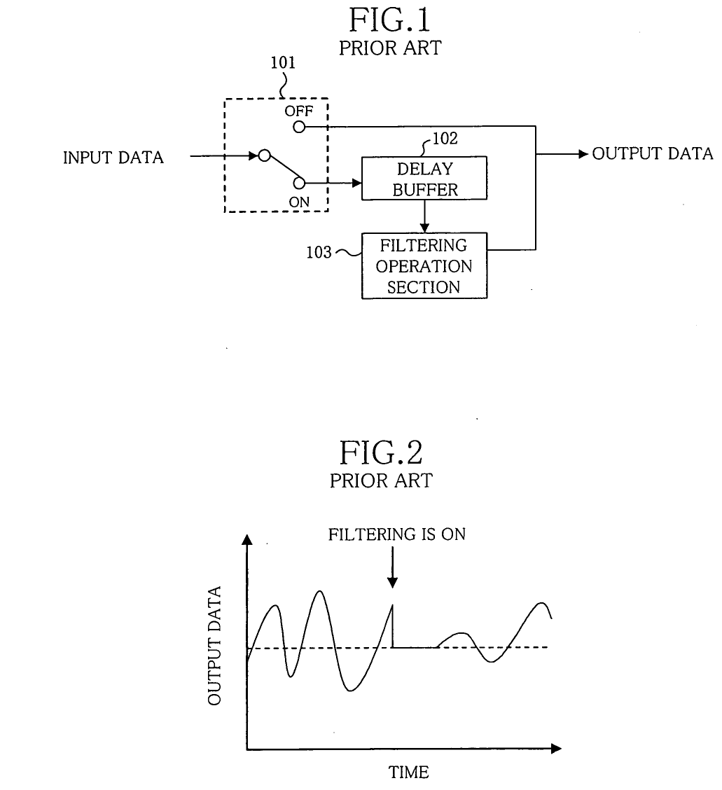

### DETAILED DESCRIPTION OF THE INVENTION

Hereinafter, detailed explanation is given of embodiments of the present invention with reference to the drawings. The following preferable embodiments are inherently presented for explanation only and do not limit the present invention, the scope of application thereof and uses thereof

### Embodiment 1

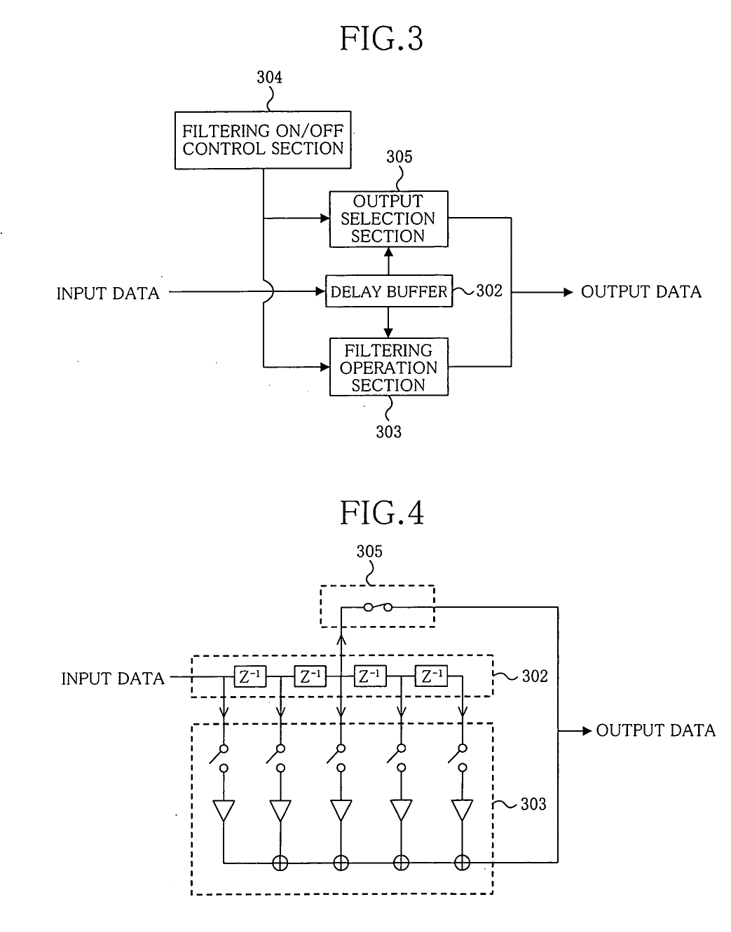

FIG. 3 is a block diagram illustrating a configuration of a signal processor according to Embodiment 1 of the present invention. In FIG. 3, reference numeral 302 is a delay buffer which sequentially delays input data to generate delay data and stores the delay data, 303 is a filtering operation section which performs a filtering operation and outputs the operation result, 304 is a filtering on/off control section which outputs a control signal for turning the filtering on or off and 305 is an output selection section which extracts and outputs specified delay data from the delay buffer 302.

Hereinbelow, an explanation is given of the performance of the signal processor. First, the delay buffer 302 receives data and sequentially delays the data to generate delay data. The delay data is stored in the delay buffer 302.

When the filtering is necessary, the filtering on/off control section 304 outputs a control signal which makes the filtering operation section 303 operative to the filtering operation section 303 and a control signal which makes the output selection section 305 inoperative to the output selection section 305.

Since the filtering operation section 303 becomes operative and the output selection section 305 is turned inoperative by these control signals, the delay data in the delay buffer 302 is sent to the filtering operation section 303. Then, the filtering operation section 303 performs a filtering operation, i.e., a sum-product operation on the delay data and a filter coefficient, thereby generating data to be output.

On the other hand, when the filtering is unnecessary, the filtering on/off control section 304 outputs a control signal which makes the filtering operation section 303 inoperative to the filtering operation section 303 and a control signal which makes the output selection section 305 operative to the output selection section 305.

Since the filtering operation section 303 becomes inoperative and the output selection section 305 is turned operative by these control signals, the output selection section 305 extracts specified delay data out of the delay data stored the delay buffer 302 and outputs the extracted data.

If an FIR filter (Finite Impulse Response filter) having a filter coefficient which is even-order symmetric and includes an odd number of taps is used as the filtering operation section 303 in the filtering-on state, a maximum filter coefficient is given to the center tap and the filter coefficient becomes even-order symmetric with respect to the center tap as a center of symmetry. Therefore, if the delay data at the center tap is extracted to output in the filtering-off state, a level difference between the output data before and after the on/off switching of the filtering is reduced.

FIG. 4 is a diagram illustrating a detailed configuration of the delay buffer 302, filtering operation section 303 and output selection section 305 shown in FIG. 3. Upon receiving the control signal output from the filtering on/off control section 304 when the filtering is unnecessary, the output selection section 305 extracts the delay data at the center tap out of the delay data stored in the delay data 302 And outputs the extracted data.

Further, if the filtering operation section 303 is an FIR filter having a filter coefficient which is even-order symmetric and includes an even number of taps, the delay data in one of two taps at the center is extracted to output.

In the thus configured signal processor according to Embodiment 1, data of 0 or almost 0 is not output even if the filtering state is switched between on and off during the data input, thereby preventing the noise from occurring.

### Embodiment 2

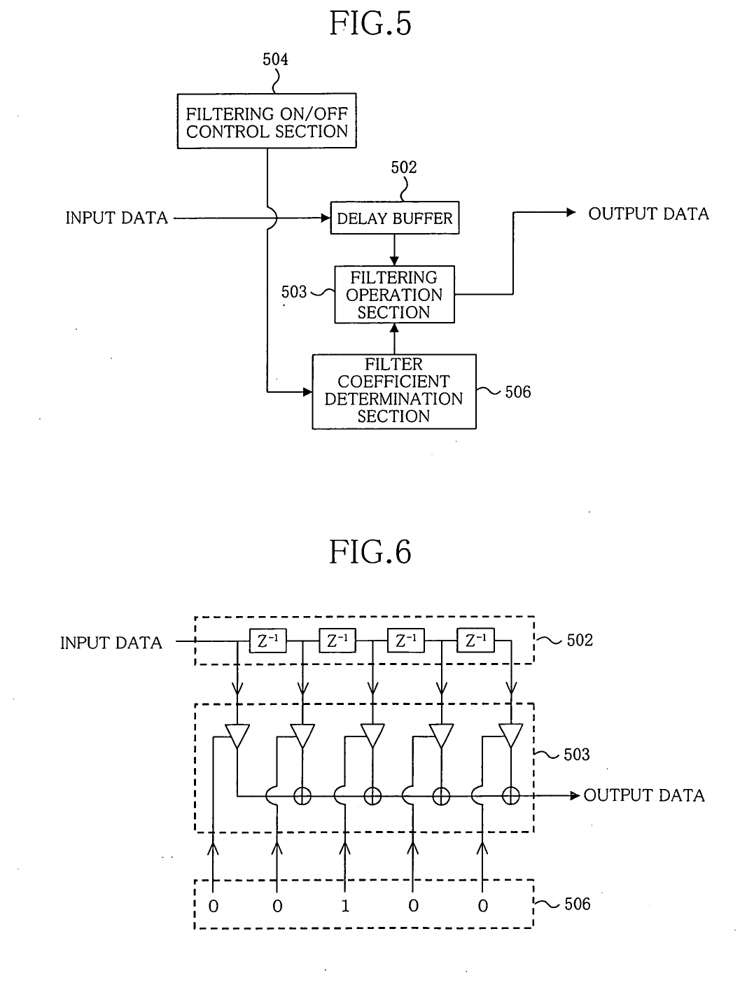

FIG. 5 is a block diagram illustrating a configuration of a signal processor according to Embodiment 2 of the present invention. In FIG. 5, reference numeral 502 is a delay buffer which sequentially delays input data to generate delay data and stores the delay data, 503 is a filtering operation section which performs a filtering operation, 504 is a filtering on/off control section which outputs a control signal for turning the filtering on or off and 506 is a filter coefficient determination section which determines a filter coefficient.

Hereinbelow, an explanation is given of the performance of the signal processor. First, the delay buffer 502 receives data and sequentially delays the data to generate delay data. The delay data is stored in the delay buffer 502.

When the filtering is necessary, a control signal for turning the filtering on is output from the filtering on/off control section 504 to the filter coefficient determination section 506.

Upon receiving the “filter-on” control signal, the filter coefficient determination section 506 determines a filter coefficient for the filtering. Then, the filtering operation section 503 performs a filtering operation, i.e., a sum-product operation on the delay data and the filter coefficient, thereby generating data to be output.

On the other hand, when the filtering is unnecessary, a control signal for turning the filtering off is output from the filtering on/off control section 504 to the filter coefficient determination section 506.

Upon receiving the “filter-off” control signal, the filter coefficient determination section 506 determines a filter coefficient for turning the filtering off Then, the filtering operation section 503 performs an operation to generate data to be output.

If an FIR filter (Finite Impulse Response filter) having a filter coefficient which is even-order symmetric and includes an odd number of taps is used as the filtering operation section 503 in the filtering-on state, a maximum filter coefficient is given to the center tap and the filter coefficient becomes even-order symmetric with respect to the center tap as a center of symmetry. Therefore, if the delay data at the center tap is extracted to output in the filtering-off state, a level difference between the output data before and after the on/off switching of the filtering is reduced.

FIG. 6 is a diagram illustrating a detailed configuration of the delay buffer 502, filtering operation section 503 and filter coefficient determination section 506 shown in FIG. 5. Upon receiving the “filter-off” signal when the filtering is unnecessary, the filter coefficient determination section 506 determines the filter coefficient for the center tap as “1” and the filter coefficient for the other taps as “0”. Then, the filtering operation section 503 performs an operation on the thus determined filter coefficients and the delay data stored in the delay buffer 502, thereby generating data to be output.

If the filtering operation section 503 is an FIR filter having a filter coefficient which is even-order symmetric and includes an even number of taps, the filter coefficient for one of two taps at the center is determined as “1” and the filter coefficient for the rest of the taps including the other of the two is determined as “0”.

In the thus configured signal processor according to Embodiment 2, data of 0 or almost 0 is not output even if the filtering is switched between on and off during the data input, thereby preventing the noise from occurring.

Thus, as described above, the present invention provides a highly practical effect of preventing the occurrence of noise accompanying the on/off switching of the filtering in a signal processor. Therefore, the present invention is significantly useful and offers excellent industrial applicability.

1. A signal processor comprising:
a delay buffer which delays input data to generate delay data and stores the delay data;
a filtering on/off control section which outputs a control signal for turning filtering on or off;
an output selection section which extracts and outputs specified delay data from the delay buffer in response to the control signal output from the filtering on/off control section; and
a filtering operation section which performs a filtering operation on the delay data stored in the delay buffer in response to the control signal output from the filtering on/off control section and outputs the operation result.

2. A signal processor comprising:
a delay buffer which delays input data to generate delay data and stores the delay data;
a filtering on/off control section which outputs a control signal for turning filtering on or off;
a filtering operation section which performs a filtering operation on the delay data stored in the delay buffer and outputs the operation result; and
a filter coefficient determination section which changes a filter coefficient of the filtering operation section in response to the control signal output from the filtering on/off control section.

3. A signal processor according to claim 2, wherein the filter coefficient determination section is so configured that a filter coefficient required for the filtering operation is determined when a control signal for turning the filtering on is output from the filtering on/off control section, or a filter coefficient for specified delay data is determined as “1” and a filter coefficient for the other delay data is determined as “0” when a control signal for turning the filtering off is output from the filtering on/off control section.
